(19) United States
(12) Patent Application Publication
(10) Pub. No.: US 2013/0256913 A1
(43) Pub. Date: Oct. 3, 2013

(54) DIE STACKING WITH COUPLED ELECTRICAL INTERCONNECTS TO ALIGN PROXIMITY INTERCONNECTS

(71) Applicants: Bryan Black, Spicewood, TX (US); Michael Su, Round Rock, TX (US); Neil McLellan, Austin, TX (US); Joe Siegel, Brookline, MA (US); Michael Alfano, Austin, TX (US)

(72) Inventors: Bryan Black, Spicewood, TX (US); Michael Su, Round Rock, TX (US); Neil McLellan, Austin, TX (US); Joe Siegel, Brookline, MA (US); Michael Alfano, Austin, TX (US)

(21) Appl. No.: 13/436,094

(22) Filed: Mar. 30, 2012

(51) Int. Cl. H01L 23/538; H01L 21/58

(52) U.S. Cl. 257/777; 438/107; 257/E23.169; 257/E21.505

(57) ABSTRACT

A method of manufacturing is provided that includes forming a first proximity interconnect on a first side of a first semiconductor chip and a first plurality of interconnect structures projecting from the first side. A second proximity interconnect is formed on a second side of a second semiconductor chip and a second plurality of interconnect structures are formed projecting from the second side. The second semiconductor chip is coupled to the first semiconductor chip so that the second side faces the first side and the first interconnect structures are coupled to the second interconnect structures. The first and second proximity interconnects cooperate to provide a proximity interface. The coupling of the first interconnect structures to the second interconnect structures provides desired vertical and lateral alignment of the first and second proximity interconnects.

### BACKGROUND OF THE INVENTION

1. Field of the Invention

This invention relates generally to semiconductor processing, and more particularly to electrical interface structures for stacked semiconductor chips and to methods of assembling the same.

2. Description of the Related Art

The performance of a semiconductor chip system is limited by, among other factors, the total power budget allowed by the system form factor, i.e., single die, stacked die, flip-chip, wire bond, etc. A significant percentage of system power is consumed by interfaces between dies. In order for system performance to continue scaling in the future, interface power must improve. Die stacking is a new technology that reduces interface power by reducing the physical distance between dies. Current die stacking technologies utilize physical interfaces, such as micro bumps, to transmit data, control signals, and power between adjacent dice.

Power consumption in stacked dice arrangements may be improved by utilizing proximity interfaces, such as capacitive or inductive, in lieu of a purely hard wired system. Capacitive and inductive interfaces use significantly lower power for data transfer. However they are difficult to construct because die to die x-y plane alignment and z-gap height requirements must be met in order to make the connection. Conventional proximity interface arrangements require the use of complex clam shell sockets to guarantee alignment. Furthermore, power delivery is still through flip-chip or wire bond interfaces.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes forming a first proximity interconnect on a first side of a first semiconductor chip and a first plurality of interconnect structures projecting from the first side. A second proximity interconnect is formed on a second side of a second semiconductor chip and a second plurality of interconnect structures are formed projecting from the second side. The second semiconductor chip is coupled to the first semiconductor chip so that the second side faces the first side and the first interconnect structures are coupled to the second interconnect structures. The first and second proximity interconnects cooperate to provide a proximity interface. The coupling of the first interconnect structures to the second interconnect structures provides desired vertical and lateral alignment of the first and second proximity interconnects.

In accordance with another aspect of an embodiment of the present invention, a method of electrically connecting a first semiconductor chip to a second semiconductor chip is provided. The method includes coupling a first plurality of interconnect structures projecting from a first side of the first semiconductor chip to a second plurality of interconnect structures projecting from a second side of the second semiconductor chip so that a first proximity interconnect on the first side of the first semiconductor chip is in desired vertical and lateral alignment with a second proximity interconnect on the second side. The first and second proximity interconnects cooperate to provide a proximity interface.

In accordance with another aspect of an embodiment of the present invention, an apparatus is provided that includes a first semiconductor chip that has a first side with a first proximity interconnect and a first plurality of interconnect structures projecting from the first side. A second semiconductor chip is coupled to the first semiconductor chip. The second semiconductor chip includes a second side facing the first side. The second side has a second proximity interconnect cooperating with the first proximity interconnect to provide a proximity interface and a second plurality of interconnect structures projecting from the second side. The first interconnect structures are coupled to the second interconnect structures to provide desired vertical and lateral alignment of the first and second proximity interconnects.

In accordance with another aspect of an embodiment of the present invention, an apparatus is provided that includes a first semiconductor chip that has a first side with a first proximity interconnect and a first plurality of interconnect structures projecting from the first side. The first interconnect structures are adapted to couple to second interconnect structures of a second semiconductor chip that has a second proximity interconnect to provide desired vertical and lateral alignment of the first and second proximity interconnects.

In accordance with another aspect of an embodiment of the present invention, a method of manufacturing is provided that includes forming a first proximity interconnect on a first side of a first semiconductor chip and a first plurality of interconnect structures projecting from the first side. The first interconnect structures are adapted to face a second side and second plurality of interconnect structures of a second semiconductor chip.

### BRIEF DESCRIPTION OF THE DRAWINGS

The foregoing and other advantages of the invention will become apparent upon reading the following detailed description and upon reference to the drawings in which:

FIG. 1 is a sectional view of an exemplary embodiment of a semiconductor chip device that may include semiconductor chips stacked and provided with a proximity interface

FIG. 2 is a portion of FIG. 1 shown a greater magnification;

FIG. 3 is a sectional view of FIG. 1 taken at section 3-3;

FIG. 4 is a portion of FIG. 2 shown a greater magnification;

FIG. 5 is a sectional view like FIG. 4, but of an alternate exemplary coupling between two electrical interconnects;

FIG. 6 is a sectional view like FIG. 5, but of another alternate exemplary coupling between electrical interconnects;

FIG. 7 is a sectional view of a small portion of a semiconductor chip undergoing exemplary barrier film processing;

FIG. 8 is a sectional view like FIG. 7, but depicting exemplary masking;

FIG. 9 is a sectional view like FIG. 8, but depicting an exemplary material deposition process to establish an exemplary electrical interconnect;

FIG. 10 is a sectional view like FIG. 9, but depicting mask removal and material removal to pattern a barrier film;

FIG. 11 is a sectional view like FIG. 10, but depicting an exemplary stacking of one semiconductor chip on another to achieve a desired vertical and lateral alignment between two proximity interconnects;

FIG. 12 is a sectional view like FIG. 11, but depicting an exemplary process for dispensing an underfill material between the two semiconductor chips; and

FIG. 13 is a pictorial view showing an exemplary semiconductor chip device exploded from an exemplary electronic device.

### DETAILED DESCRIPTION OF SPECIFIC EMBODIMENTS

Various stacked semiconductor chip arrangements are disclosed. The disclosed embodiments incorporate a proximity interconnect on one chip cooperating with another proximity interconnect on another semiconductor chip to establish a proximity interface for transferring power, ground or signals. Plural electrical interconnects of the first semiconductor chip are coupled to plural electrical interconnects of the second semiconductor chip so that desired vertical and lateral alignment of the proximity interconnects is achieved. Micro bumps are one example of the electrical interconnects. Additional details will now be described.

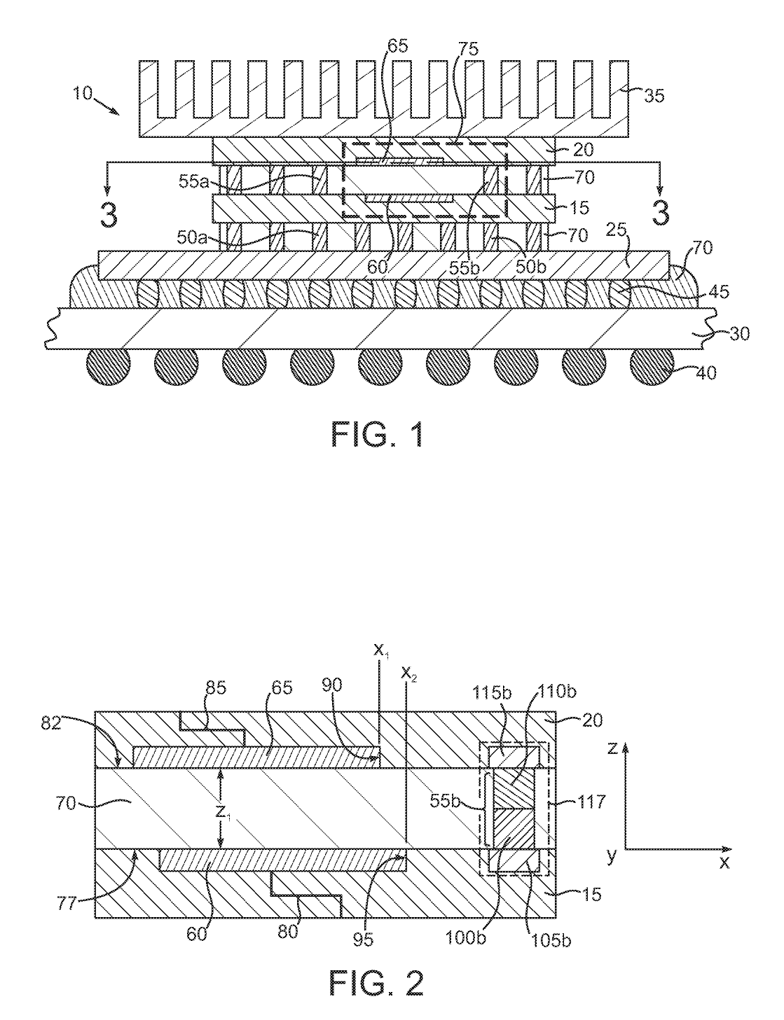

In the drawings described below, reference numerals are generally repeated where identical elements appear in more than one figure. Turning now to the drawings, and in particular to FIG. 1, therein is shown a sectional view of an exemplary embodiment of a semiconductor chip device 10 that may include semiconductor chips 15 and 20 stacked on a substrate 25. The substrate 25 may in turn be mounted on a circuit board 30. A heat sink 35 may be seated on the semiconductor chip 20. None of the embodiments disclosed herein is reliant on particular functionalities of the semiconductor chips 15 and 20, the substrate 25 or the circuit board 30. Thus, the semiconductor chips 15 and 20 may be any of a variety of different types of circuit devices used in electronics, such as, for example, microprocessors, graphics processors, combined microprocessor/graphics processors, application specific integrated circuits, memory devices or the like, and may be single or multi-core. The semiconductor chips 15 and 20 may be constructed of bulk semiconductor, such as silicon or germanium, or semiconductor on insulator materials, such as silicon-on-insulator materials. In addition, any of the semiconductor chips 15 and 20 may be configured as a semiconductor interposer, and thus as used herein, the term “chip” is intended to encompass both semiconductor chips and interposers. Here, the semiconductor chip device 10 includes two semiconductor chips 15 and 20 in a stack. However, more than two may be used.

The substrate 25 may be a semiconductor chip of the type described above or a circuit board, such as a semiconductor chip package substrate, circuit card or other. In an exemplary embodiment, the substrate 25 may be implemented as a processor, such as a graphics processing unit, and the semiconductor chips 15 and 20 configured as memory devices.

The circuit board 30 may be a semiconductor chip package substrate, a circuit card, or virtually any other type of printed circuit board. Although a monolithic structure could be used for the circuit board 30, a more typical configuration will utilize a build-up design. In this regard, the circuit board 30 may consist of a central core upon which one or more build-up layers are formed and below which an additional one or more build-up layers are formed. The core itself may consist of a stack of one or more layers. So-called “coreless” designs may be used as well. The layers of the circuit board 30 may consist of an insulating material, such as various well-known epoxies or other resins interspersed with metal interconnects. A multi-layer configuration other than buildup could be used. Optionally, the circuit board 30 may be composed of well-known ceramics or other materials suitable for package substrates or other printed circuit boards.

The optional heat sink 35 may be positioned on the semiconductor chip 30 and constructed of well-known heat sink materials, such as copper, aluminum, stainless steel or others, and take on a variety of mechanical configurations.

The circuit board 30 may electrically interface with another electronic device (not shown) by various types of interconnects such as the depicted ball grid array 40, or optional pin grid arrays, land grid arrays or other types of interconnect structures. The substrate 25 may be electrically connected to the circuit board 30 by way of various types of interconnect structures, such as the solder joints 45. Optionally, copper pillar plus solder or other types of interconnect structures might be used. The semiconductor chip 15 may be electrically connected to the substrate 25 by way of plural interconnect structures, two of which are labeled 50a and 50b. The semiconductor chip 20 may be electrically connected to the semiconductor chip 15 and vice versa by way of similar electrical interconnects, two of which are labeled 55a and 55b. The interconnects 50a, 50b, 55a and 55b may be used to transmit power ground and/or signals.

The electrical interfaces 50a, 50b, 55a and 55b may be constructed as micro bumps, conductive pillars plus solder or other types of interconnects. Exemplary materials include copper, aluminum, gold, platinum, palladium, silver, combinations of these or others.

In addition to the 50a, 50b, 55a and 55b “wired” interconnects, a proximity interface between the semiconductor chips 15 and 20 may be established by the cooperation between a proximity interconnect 60 of the semiconductor chip 15 and a proximity interconnect 65 of the semiconductor chip 20. The proximity interconnects 60 and 65 may be capacitor plates for capacitive transmission or inductors for inductive transmission. Whether capacitive or inductive, the proximity interconnects 60 and 65 may be similarly used to transmit power, ground or signal. The proximity interconnects 60 and 65 may be better suited to transmit signal than power due to efficiency considerations. However, such considerations do not preclude the usage of the interfaces 60 and 65 to transmit power. The proximity interconnects 60 and 65 may be composed of a variety of conductor materials, such as copper, aluminum, gold, platinum, palladium, silver, combinations of these or others.

An underfill material 70 may be applied between the semiconductor chip 15 and the substrate 25 and between the chips 15 and 20. The underfill 70 is designed to lessen the effects of differences in coefficients of thermal expansion of those devices.

Additional features of the semiconductor chips 15 and 20, the interconnect 55b and the proximity interconnects 60 and 65 may be understood by referring now to FIG. 2, which is the portion of FIG. 1 circumscribed by the dashed rectangle 75. The description of the interconnect 55b shown in FIG. 2 that follows will be illustrative of the other labeled interconnects 50a, 50b and 55a and the others that are not separately labeled in FIG. 1. The proximity interconnect 60 may be fabricated on the side 77 of the semiconductor chip 15 as a metallic pad or plate or as a coil if desired in the event that an inductive type interface is desired. The proximity interconnect 60 may be connected to other circuitry or electrical pathways by way of the schematically represented electrical pathway 80. The proximity interconnect 65 may be fabricated on the side 82 of the semiconductor chip 15 facing the side 77 as a metallic pad or plate or as a coil if desired in the event that an inductive type interface is desired. The proximity interconnect 65 may be similarly electrically connected to other areas by way of the schematically represented conductive pathway 85. The conductive pathways 80 and 85 may consist of multiple conductor layers connected vertically by vias or other devices.

The semiconductor chips 15 and 20 are stacked so as to provide a desired vertical alignment or spacing z₁ between the proximity interconnects 60 and 65 that yields desired transmission properties. The value z₁ will depend upon several factors, such as the size and conductivity of the proximity interconnects 60 and 65, the dielectric constant of the underfill 70 (or air in the event there is no underfill 70) and the lateral or x-y plane alignment of the proximity interconnects 60 and 65. For the purposes of this illustration, it is assumed the right edge 90 of the proximity interconnect 65 has some position x₁ relative to the x-axis while the right edge 95 of the proximity interconnect 60 has a position x₂ offset from x₁. This is not to say that the offset between x₂ and x₁ is desired, rather that it is a phenomena that can occur during the manufacturing process since absolutely perfect spatial alignment between two vertically spaced structures is sometimes difficult to achieve. The material point here is that even though there may be some offset x₂−x₁, the usage of micro bump style interconnects, such as the interconnect 55b, may be used to establish not only a desired vertical alignment buy also a x-y plane alignment between the chips 15 and 20 and thus the proximity interconnects 60 and 65 may be achieved efficiently.

Still referring to FIG. 2, the following description of the interconnect 55b will be illustrative of the other interconnect structures 50a, 50b and 55a. The interconnect structure 55b may be a combination of a micro bump 100b connected to a conductor pad 105b of the semiconductor chip 15 and a micro bump 110b connected to a conductor pad 115b of the semiconductor chip 20. Again, the micro bumps 100b and 110b may be composed of a variety of conductor materials, such as copper, aluminum, gold, platinum, palladium, silver, combinations of these or others. Note the location of the dashed rectangle 117. The portion of FIG. 2 circumscribed by the dashed rectangle 117 will be presented in a subsequent figure and used below to describe additional details of the micro bumps 100b and 110b.

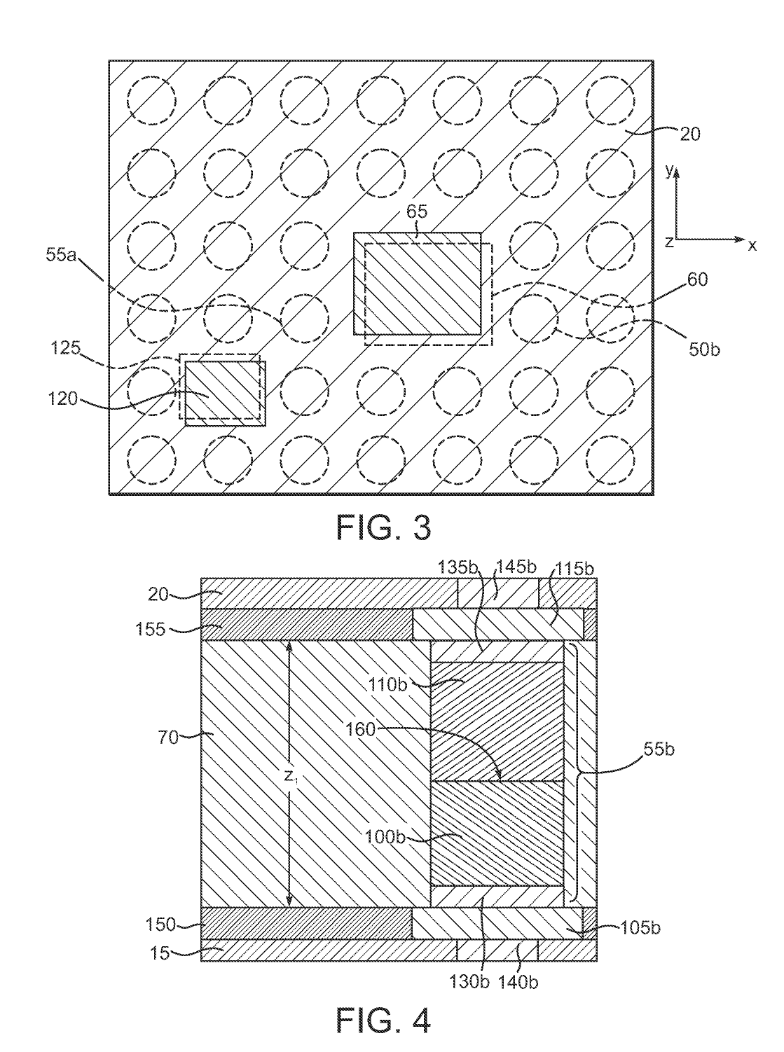

It should be understood that more than a single proximity interface may be implemented between the semiconductor chips 15 and 20. In this regard, attention is now turned to FIG. 3, which is a sectional view of FIG. 1 taken at section 3-3. Before turning to FIG. 3 in earnest, it should be noted that section 3-3 passes through the lower portion of the semiconductor chip 20 and through the proximity interconnect 65. As a result, the proximity interconnect 65 appears with crosshatching in FIG. 3 but the underlying proximity interconnect 60 of the semiconductor chip 15 and the electrical interconnects 55a and 55b are obscured and thus appear dashed. As noted above, the proximity interconnect 60 in this illustration is hypothetically misaligned or offset along the x-axis relative to the proximity interconnect 65 as shown. In addition, the proximity interconnect 60 may be misaligned along the y-axis relative to the proximity interconnect 65 as shown. Again, some amount of misalignment along the x-axis or y-axis is tolerated and may be kept to a comfortable minimum by using the alignment and ultimate bonding of the micro bumps 100b and 110b shown in FIG. 2 and the corresponding others that are not labeled separately. In addition, and as just noted, additional proximity interconnects such as the proximity interconnect 120 of the semiconductor chip 20 and the proximity interconnect 125 of the semiconductor chip 20 (again shown in dashed since that structure is underlying the visible surface of the semiconductor chip 20). Here, the proximity interconnect 120 is slightly out of alignment both along the x-axis and y-axis relative to the underlying proximity interconnect 125. The proximity interconnects 60, 65, 120 and 125 have the rectangular footprints as shown, or virtually any other footprint. Indeed, if inductive transfer is desired, coil structures may be appropriate.

Additional details of the interconnect structure 55b shown in FIG. 2 may be understood by referring now to FIG. 2 and to FIG. 4, which is the portion of FIG. 2 circumscribed by the dashed rectangle 117 shown at greater magnification. Referring specifically to FIG. 4, and as noted above, the interconnect structure 55b may include the micro bumps 100b and 110b electrically connected to the conductor pads 105b and 115b of the semiconductor chips 15 and 20, respectively. In the event that the micro bumps 100b and 110b are composed of gold or a like material that will benefit from the usage of barrier films, a barrier film 130b may be formed between the micro bump 100b and the underlying conductor pad 105b and a corresponding barrier film 135b may be fabricated between the micro bump 110b and the conductor pad 115b. The barrier films 130b and 135b may be fabricated from materials that can act as barriers to diffusion and that adhere to the micro bumps 100b and 110b. Examples includes tantalum and tantalum nitride. The conductor pads 105b and 115b may be electrically connected to other portions of the semiconductor chips 15 and 20, respectively, in a variety of ways, such as, for example, by the thru-silicon vias 140b and 145b. Optionally, other types of interconnect structures, such as multi-level metallization with conductive vias or other types of electrical pathways may be used. The conductor pads 105b and 115b may be surrounded laterally by dielectric layers 150 and 155, which may be inter level dielectric layers or other types of insulating layers composed of a variety of materials, such as silicon dioxide, silicon nitride, polyimide, tetra-ethyl-ortho-silicate or others. In the illustrative embodiment depicted in FIG. 4, the micro bumps 100b and 110b may be bonded at the interface 160 by thermal compression bonding. Where the underfill 70 is used, successful capillary dispensing may require a minimum value of z₁ on the order of 50 microns depending on device geometry and the density of the interconnects 55b and the others shown in FIG. 1. Where the underfill 70 is not used, the spacing z₁ can be closer to 10 microns, again depending on device geometry.

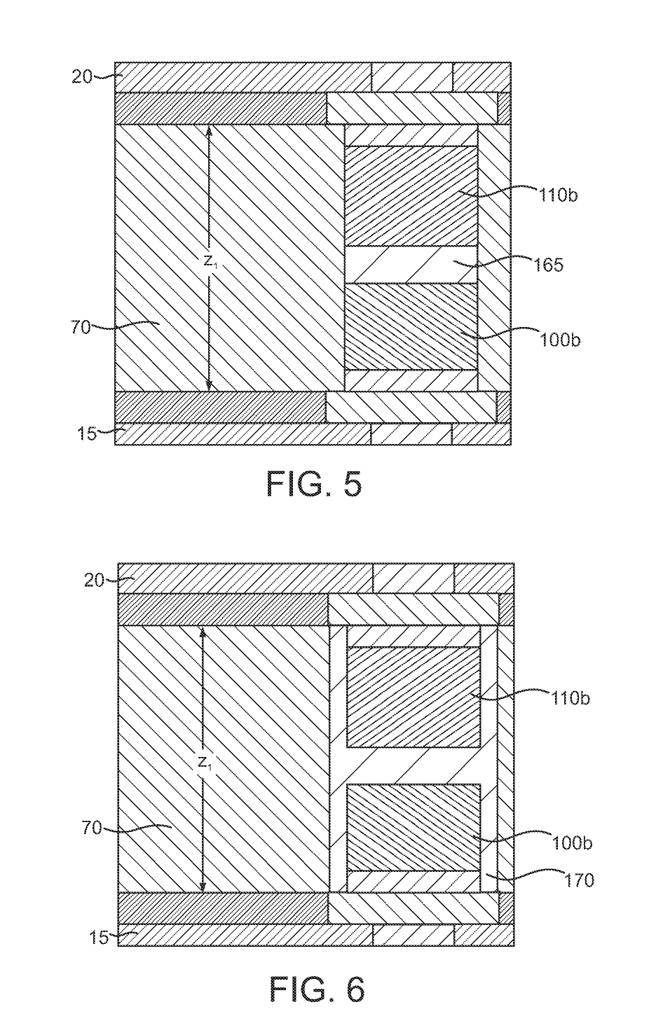

Optionally, other types of joining techniques may be used to connect the micro bumps 105b and 110b of the semiconductor chips 15 and 20, respectively. For example, and as shown in FIG. 5, the micro bumps 100b and 110b may be joined by a solder interface 165. The solder interface 165 may be the metallurgical combination of respective solder portions that are initially formed on the micro bumps 100b and 110b that are later joined together in a reflow process, optionally, a single solder cap may be placed on one or the other of the micro bumps 100b and 110b and thereafter suitable for reflow process used to establish the solder interface 165. Various lead or lead-free solders may be used, such as tin-lead (about 63% Sn and 37% Pb), tin-silver (about 97.3% Sn 2.7% Ag), tin-copper (about 99% Sn 1% Cu), tin-silver-copper (about 96.5% Sn 3% Ag 0.5% Cu) or the like. The direct interface 160 shown in FIG. 4 or the solder interface 165 shown in FIG. 5 are designed to yield the desired vertical spacing z₁ between the semiconductor chips 15 and 20 to yield the design spacing for the proximity interconnects 60 and 65 shown in FIGS. 1 and 2. Again, the underfill 70 is optional.

In still another alternative shown in section in FIG. 6, solder cladding 170 may be used to establish a metallurgical bond between the micro bumps 100b and 110b of the semiconductor chips 15 and 20, respectively. The solder cladding 170 may be composed of the solders described above and tailored to yield the desired vertical spacing z₁. The underfill 70 is optional.

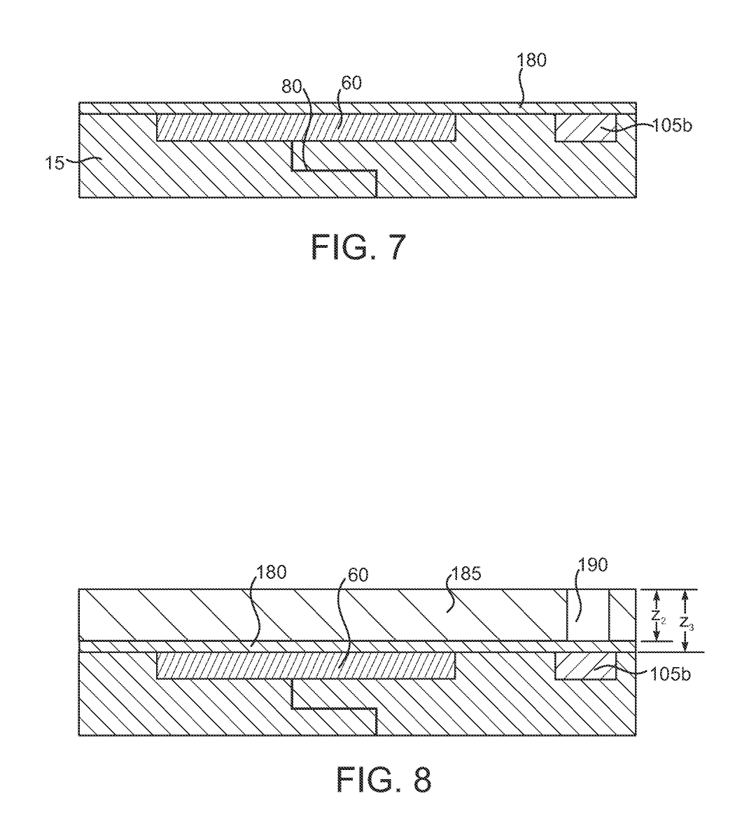

An exemplary method for fabricating the proximity interconnect 60 and the electrical interconnect 55b depicted in FIGS. 1 and 2 may be understood by referring now to FIGS. 7, 8, 9, 10 and 11 and initially to FIG. 7. The description that follows will be illustrative of the other proximity interconnect 65 and interconnects 50a, 50b, etc. shown in FIG. 1. Attention is turned to FIG. 7, which is a sectional view of a small portion of the semiconductor chip 15 that is depicted in FIG. 2 but shown at a slightly greater magnification and at a preliminary stage of processing. At this point, the proximity interconnect 60, the electrical pathway 80 and the conductor pad 105b have been constructed. The proximity interconnect 60 may be fabricated from a variety of materials in a variety of ways. For example, copper may be plated, first as a seed layer in an electroless process and followed by a biased plating process. Appropriate masking (not shown) may be used to isolate the portion of the semiconductor chip 15 where the plating process will occur. Similar types of materials and processes may be used to establish the conductor pad 105b. At this point, the semiconductor chip 15 may be blanket coated with a barrier material layer 180 that may be composed of, for example, tantalum nitride and tantalum. The type of material appropriate for the layer 180 will depend on the compositions of the conductor pad 105b and the later-formed micro bump.

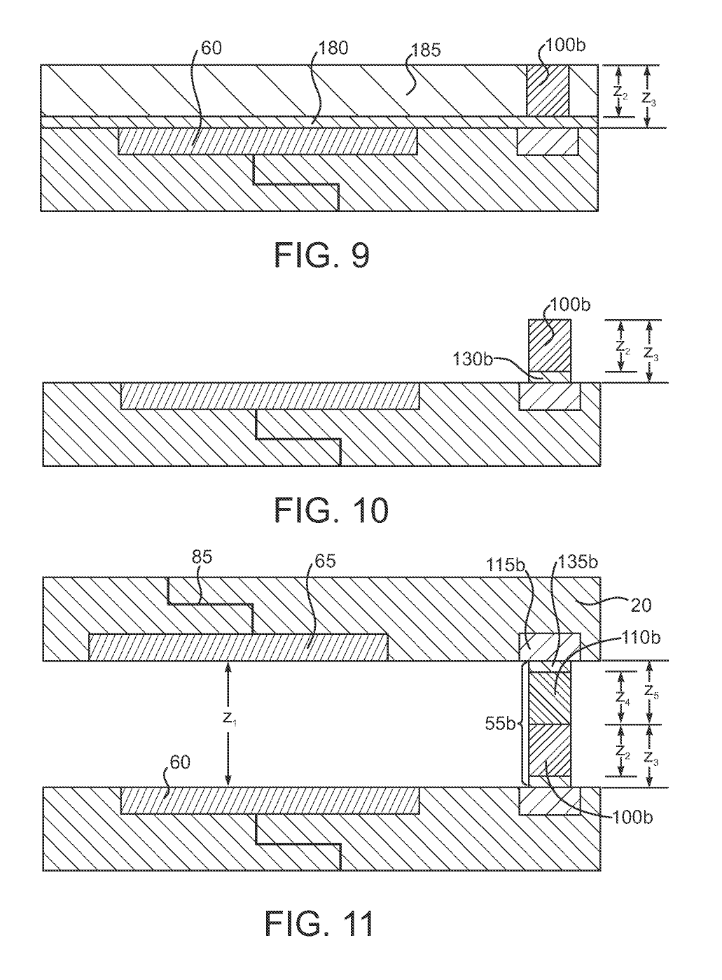

Next and as shown in FIG. 8, a suitable lithography mask 185 may be applied to the barrier material layer 180 and then suitably patterned with an opening 190 over the position of the conductor pad 105b. The mask 185 is applied to a thickness z₂ relative to the upper surface of the barrier layer 180 and a height z₃ relative to the upper surface of the proximity interconnect 60 such that the thickness of the barrier material layer 180 is given by z₃−z₂. The thickness z₃ will determine in part the ultimate spacing z₁ depicted in FIG. 2 between the semiconductor chips 15 and 20. Thus, the values z₃ and z₃−z₂ should be selected with these considerations in mind. Next and as shown in FIG. 9, suitable material deposition process may be used to establish the micro bump 100b using the mask 185. Again the combined height of the micro bump 100b relative to the proximity interconnect 60 is given by z₃−z₂. The material deposition of the micro bump 100b may be performed in a variety of ways such as plating, chemical vapor deposition, sputtering or others. In an exemplary embodiment, gold may be flash plated.

Next and as shown in FIG. 10, the lithography mask 185 depicted in FIG. 9 may be stripped by ashing, solvent stripping or other material removal techniques, to leave the micro bump 100b. Thereafter, an etch process may be used to remove exposed portions of the barrier film 180 shown in FIG. 9 to leave the patterned barrier layer 130b. The micro bump 100b and the barrier film 130b have a combined height z₃.

The semiconductor chip 20 may be stacked on the semiconductor chip 15 as shown in FIG. 11. Prior to the stacking operation, a similar set of processes may be performed on the semiconductor chip 20 to yield the micro bump 110b, the barrier layer 135b, the conductor pad 115b and the proximity interconnect 65 and the electrical pathway 85. The semiconductor chip 20 may be flipped over and mounted on the semiconductor chip 15 using the electrical interconnect 55b and the other corresponding electrical interconnects that are not shown in FIG. 11 as alignment structures so that the proximity interconnects 60 and 65 are vertically aligned with the desired spacing z₁ and as close to being in desired x-y plane alignment as possible. Thereafter, a process to join the micro bumps 100b and 110b such as thermal compression bonding, solder reflow or other techniques may be performed in order to finish the interconnect 55b. Here, the micro bump 100b has a thickness z₄ and in conjunction with the barrier film 135b has some total thickness z₅ such that z₃+z₅ yields the desired gap z₁.

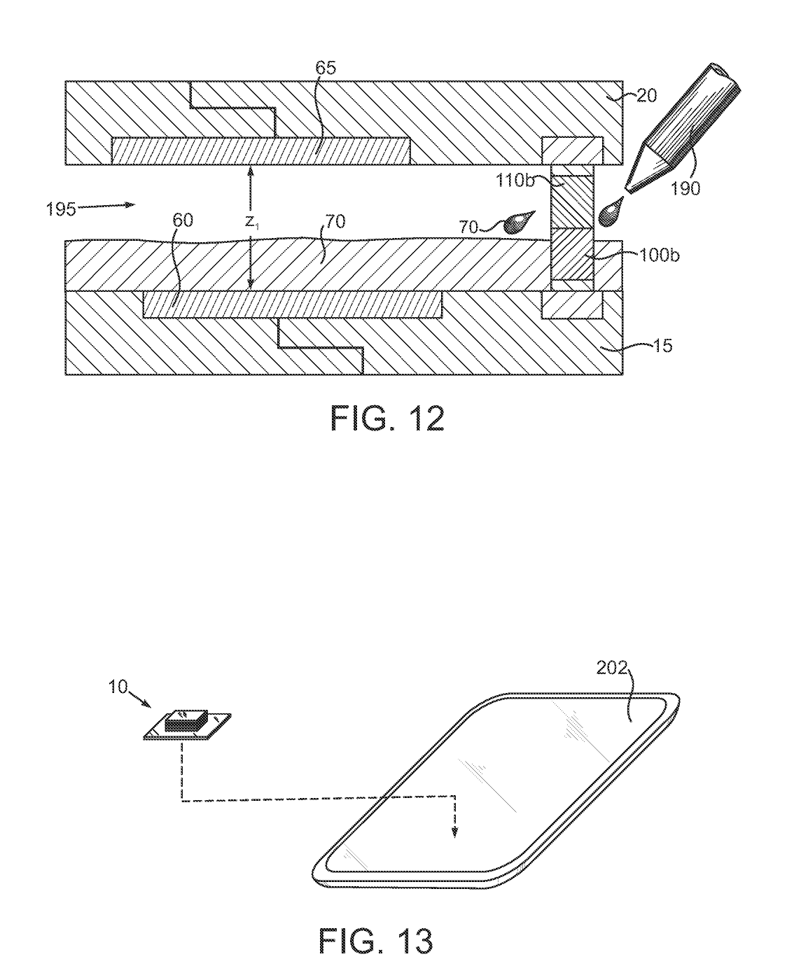

Following the merging of the micro bumps 100b and 110b, the underfill 70 may be dispensed between the semiconductor chips 15 and 20 as shown in FIG. 12 by a suitable applicator 190. Capillary action may be used. Some form of pressurized application could be used as desired. The ability to use capillary action alone to ensure that the underfill 70 completely fills the space 195 between the semiconductor chips will depend upon the density of the interconnects 55b and the others not labeled, the diameter or lateral dimension of the interconnects 55b as well as the spacing z₁ and the viscosity of the underfill 70. As noted above, it may be possible to eliminate the use of the underfill 70 altogether in which case the electrical performance of the cooperation between the proximity interconnects 60 and 65 may be even greater due to the usage of an air gap alone. The above steps may be repeated if additional chips will be stacked.

In lieu of capillary action, an underfill application may precede chip stacking and interconnect bonding, particularly where thermal compression bonding is used to establish bonding between the interconnect structures of the semiconductor chips 15 and 20. In one embodiment, a non-conducting paste (NCP) is applied to one or the other of the semiconductor chips 15 and 20 and then the chips 15 and 20 are stacked and interconnect bonding, such as by thermal compression bonding, is performed. In another embodiment, a non-conducting film (NCF) may be used in lieu of or with an NCP. It may be possible to combine NCP and NCF. A NCP could be used nearer central regions and a NCF at the perimeters of the semiconductor chips 15 and 20 or vice versa. Stacking and thermal compression bonding will follow.

Any of the disclosed embodiments of the semiconductor chip device 10 may be incorporated into another electronic device such as the electronic device 202 depicted in FIG. 13. The electronic device 202 may be a computer, a server, a hand held device, or virtually any other electronic component.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
forming a first proximity interconnect on a first side of a first semiconductor chip and a first plurality of interconnect structures projecting from the first side;
forming a second proximity interconnect on a second side of a second semiconductor chip and a second plurality of interconnect structures projecting from the second side; and
coupling the second semiconductor chip to the first semiconductor chip so that second side faces the first side and the first interconnect structures are coupled to the second interconnect structures, the first and second proximity interconnects cooperating to provide a proximity interface and the coupling of the first interconnect structures to the second interconnect structures providing desired vertical and lateral alignment of the first and second proximity interconnects.

2. The method of claim 1, wherein the first and second proximity interconnects comprise capacitive interconnects.

3. The method of claim 1, wherein the first and second proximity interconnects comprise inductive interconnects.

4. The method of claim 1, wherein the first interconnect structures and the second interconnect structures comprise micro bumps.

5. The method of claim 1, wherein the first interconnect structures are coupled to the second interconnect structures by direct thermal bonding.

6. The method of claim 1, wherein the first interconnect structures are coupled to the second interconnect structures by solder.

7. The method of claim 1, comprising the first semiconductor chip coupled to a substrate.

8. The method of claim 1, comprising mounting the apparatus in an electronic device.

9. A method of electrically connecting a first to a second semiconductor chip, comprising:
coupling a first plurality of interconnect structures projecting from a first side of the first semiconductor chip to a second plurality of interconnect structures projecting from a second side of the second semiconductor chip so that a first a first proximity interconnect on the first side of the first semiconductor chip is in desired vertical and lateral alignment with a second proximity interconnect on the second side, the first and second proximity interconnects cooperating to provide a proximity interface.

10. The method of claim 9, wherein the first and second proximity interconnects comprise capacitive interconnects.

11. The method of claim 9, wherein the first and second proximity interconnects comprise inductive interconnects.

12. The method of claim 9, wherein the first interconnect structures and the second interconnect structures comprise micro bumps.

13. The method of claim 9, comprising transmitting at least one of power, ground or signals across the proximity interface.

14. The method of claim 9, comprising transmitting at least one of power, ground or signals between the first interconnect structures and the second interconnect structures.

15. An apparatus, comprising:
a first semiconductor chip including a first side having a first proximity interconnect and a first plurality of interconnect structures projecting from the first side;
a second semiconductor chip coupled to the first semiconductor chip, the second semiconductor chip including a second side facing the first side, the second side having a second proximity interconnect cooperating with the first proximity interconnect to provide a proximity interface and a second plurality of interconnect structures projecting from the second side; and
wherein the first interconnect structures are coupled to the second interconnect structures to provide desired vertical and lateral alignment of the first and second proximity interconnects.

16. The apparatus of claim 15 wherein the first and second proximity interconnects comprise capacitive interconnects.

17. The apparatus of claim 15, wherein the first and second proximity interconnects comprise inductive interconnects.

18. The apparatus of claim 15, wherein the first interconnects structures and the second interconnect structures comprise micro bumps.

19. The apparatus of claim 15, wherein the first interconnect structures are coupled to the second interconnect structures by direct thermal bonding.

20. The apparatus of claim 15, wherein the first interconnect structures are coupled to the second interconnect structures by solder.

21. The apparatus of claim 15, comprising a substrate, the first semiconductor chip being coupled to the substrate.

22. The apparatus of claim 15, comprising an electronic device, the apparatus being mounted in the electronic device.

23. An apparatus, comprising:
a first semiconductor chip including a first side having a first proximity interconnect and a first plurality of interconnect structures projecting from the first side; and
wherein the first interconnect structures are adapted to couple to second interconnect structures of a second semiconductor chip having a second proximity interconnect to provide desired vertical and lateral alignment of the first and second proximity interconnects.

24. The apparatus of claim 23, wherein the first and second proximity interconnects comprise capacitive interconnects.

25. The apparatus of claim 23, wherein the first and second proximity interconnects comprise inductive interconnects.

26. The apparatus of claim 23, wherein the first interconnects structures and the second interconnect structures comprise micro bumps.

27. The apparatus of claim 23, comprising the second semiconductor chip coupled to the first semiconductor chip.

28. A method of manufacturing, comprising:
forming a first proximity interconnect on a first side of a first semiconductor chip and a first plurality of interconnect structures projecting from the first side, the first plurality of interconnect structures being adapted to face a second side and second plurality of interconnect structures of a second semiconductor chip.

29. The method of claim 28, wherein the first proximity interconnects comprises a capacitive interconnect.

30. The method of claim 28, wherein the first proximity interconnect comprises an inductive interconnect.

31. The method of claim 28, wherein the first interconnect structures comprise micro bumps.

32. The method of claim 28, comprising coupling the second semiconductor chip to the first semiconductor chip so that second side faces the first side and the first interconnect structures are coupled to the second interconnect structures, the first and second proximity interconnects cooperating to provide a proximity interface and the coupling of the first interconnect structures to the second interconnect structures providing desired vertical and lateral alignment of the first and second proximity interconnects.

33. The method of claim 32, wherein the second proximity interconnect comprises a capacitive interconnect.

34. The method of claim 32, wherein the second proximity interconnect comprises an inductive interconnect.

35. The method of claim 32, wherein the second interconnect structures comprise micro bumps.

36. The method of claim 32, wherein the first interconnect structures are coupled to the second interconnect structures by direct thermal bonding.
